(19) United States
(12) Patent Application Publication
(10) Pub. No.: US 2015/0305205 A1
(43) Pub. Date: Oct. 22, 2015

(54) Kinetic-Heat-Sink-Cooled Server

(71) Applicant: COOLCHIP TECHNOLOGIES, INC., Somerville, MA (US)

(72) Inventors: Lino A. Gonzalez, Somerville, MA (US); Pramod Chamarthy, Plano, TX (US); Steven Stoddard, Boston, MA (US); William R. Sanchez, Somerville, MA (US); Roger B. Dickinson, Torrington, CT (US)

(21) Appl. No.: 14/648,614

(22) PCT Filed: Dec. 3, 2013
(86) PCT No.: PCT/US2013/072861

§ 371 Date: May 29, 2015

Related U.S. Application Data
(60) Provisional application No. 61/732,832, filed on Dec. 3, 2012.

(51) Int. Cl. H05K 7/20

(52) U.S. Cl. CPC H05K 7/20718; H05K 7/20436

(57) ABSTRACT

A rack server has a base supporting a plurality of circuit elements, and a kinetic heat sink in direct contact with at least one first circuit element. The direct contact is configured to produce a heat-conduction relationship between the at least one first circuit element and the kinetic heat sink. The kinetic heat sink has a radial side spanning 360 degrees. The rack server also has a member for radially directing air from the kinetic heat sink. The member has an exhaust port spanning no more than about 180 degrees of the radial side, and the kinetic heat sink is configured to exhaust air from no more than about 180 degrees of the radial side. The exhaust port faces at least one second circuit element and is configured to direct air toward the at least one second circuit element.

### PRIORITY

This patent application claims priority from provisional U.S. patent application No. 61/732,832, filed Dec. 3, 2012, entitled, “Server-Based Kinetic Heat Sink,” and naming Lino A. Gonzalez, Pramod Chamarthy, Steven Stoddard, William R. Sanchez, and Roger B. Dickinson as inventors, the disclosure of which is incorporated herein, in its entirety, by reference.

### GOVERNMENT LICENSED RIGHTS

This invention was made with government support under contract no. 1315258 awarded by the National Science Foundation. The government has certain rights in the invention.

### FIELD OF THE INVENTION

The invention generally relates to heat-extraction and dissipation devices and, more particularly, the invention relates to a kinetic heat sink for use with electronic components.

### BACKGROUND OF THE INVENTION

Small form-factor servers (such as 1U and blade servers) allow for more processing density than larger-sized servers. Undesirably, these servers often are more difficult to cool for the same reason—because of their small size.

Traditional methods, such as finned heat sinks coupled with an array of case fans, are less efficient because a small fan (e.g., 40-mm diameter) is less efficient at generating airflow compared to a fan with a larger blade. Other methods, such a liquid cooling, add complexity and cost while taking up valuable real-estate within the server. Rack based solutions are available, but similarly add complexity and cost.

### SUMMARY OF VARIOUS EMBODIMENTS

In accordance with one embodiment of the invention, a rack server has a base supporting a plurality of circuit elements, and a kinetic heat sink in direct contact with at least one first circuit element. The direct contact is configured to produce a heat-conduction relationship between the at least one first circuit element and the kinetic heat sink. The kinetic heat sink has a radial side spanning 360 degrees. The rack server also has a member for radially directing air from the kinetic heat sink. The member has an exhaust port spanning no more than about 180 degrees of the radial side, and the kinetic heat sink is configured to exhaust air from no more than about 180 degrees of the radial side. The exhaust port faces at least one second circuit element and is configured to direct air toward the at least one second circuit element, which preferably includes at least one peripheral circuit element.

The exhausted air is preferably configured by the exhaust port as a vector of air that is directed toward the peripheral-circuit elements. The server may include duct structures operatively connected to the exhaust port. The duct structures may be configured to focus the exhaust air of the exhaust port toward the at least one peripheral-circuit element.

In another embodiment, the rack server may include a kinetic-heat-sink housing that forms a chamber for containing the thermal base structure and rotating structure of the kinetic heat sink. The housing may also form the exhaust port, which is located at one end of the chamber.

The kinetic heat sink may draw air from the front portion through the housing and expel the air to the rear portion. The server housing may be configured to be mounted to a server rack in a prescribed manner in which a front portion of the housing faces the front of the server rack. The housing may include an intake port that spans up to 360 degrees of the kinetic heat sink. The kinetic heat sink may draw air at a flow rate measuring between 15 and 45 cubic feet per minute (CFM). The housing may form a gap with the rotating structure for the air to circulate around it. The gap measures preferably at least 3 mm, more preferably between 5 and 10 mm at its minimum distance. The gap may increase angularly to at least 20 mm, even more between 20 and 50 mm, even more preferably at about 45 mm.

In certain embodiments, such as in a 1U form-factor rack server, the kinetic heat sink may exhaust air at a flow rate measuring preferably up to 50 cubic feet per minute (CFM), even more preferably between 15 and 45 CFM. The kinetic heat sink may consume power measuring preferably up to 10 Watts (W), more preferably between 4 and 6 Watts to produce the lower flow rates (e.g., at about 15 CFM).

In preferred embodiments, the kinetic heat sink comprises a thermal base structure in contact with the at least one first circuit element and a rotating structure spaced from the base structure by an air gap. This air gap measures preferably less than 100 micrometer (um), more preferably between 5 um and 100 um, and even more preferably between 5 um and 50 um when the rotating structure is rotating. When rotating, the thermal resistance measures preferably less than about 0.33 Celsius per Watt (° C./W). The rotating structure has a footprint measuring preferably between 10 and 20 squared inches (in²).

To cool multiple circuit elements (e.g., processing component), the rack server may have at least a second kinetic heat sink. In preferred embodiments, each kinetic heat sink is coupled to a single processing component. A processing component may be a microprocessor that houses at least one processing core. To that end, a second kinetic sink may also be in direct contact with a second processing component and has a heat-conduction relationship therewith. The second kinetic heat sink may have a radial side spanning 360 degrees from which air is forced when the second kinetic heat sink is rotating, which draws heat from the second processing component through the heat-conduction relationship. A second member (e.g., a wall, a duct, or housing) may radially direct the forced air from the second kinetic heat sink to a second exhaust port that spans no more than about 180 degrees of the radial side of the second kinetic heat sink. The exhausted air is preferably configured by the second exhaust port as a vector of air that is directed toward the same or different peripheral-circuit elements. The second kinetic heat sink may have a second rotating structure spaced from the base structure by a second air gap in which the gap is less than about 100 microns.

In certain embodiments, at least two kinetic heat sinks may share a common thermal base structure in direct contact with at least two processing components. The kinetic heat sink may have at least two rotating structures in which each are spaced less than about 100 microns from the thermal base structure, when the heat sink is operating.

In another embodiment, to cool at least two processing component, the kinetic heat sink may have a single rotating structure that spans a substantial portion of the thermal base structure.

In certain embodiments, the rack server has a server housing that contains the base, the kinetic heat sink, and the kinetic heat sink housing. In other embodiments, the server housing also serves as the kinetic heat sink housing. The housing may include a wall structure to separate the exhaust air of the exhaust port toward the at least one second circuit element.

In accordance with another embodiment of the invention, a method of thermally controlling the interior of a rack server mounts at least one kinetic heat sink to an integrated circuit within a rack server having a base supporting the integrated circuit and a plurality of other circuit elements. This mounting produces a direct heat-conduction relationship between the kinetic heat sink and the integrated circuit. The rack server has a front and a rear, and the kinetic heat sink has an exhaust port spanning no more than about 180 degrees of the kinetic heat sink. The method then orients the exhaust port of the kinetic heat sink to direct the majority of its airflow toward the rear of the rack server. At least one other circuit element preferably is between the kinetic heat sink and the rear to receive the airflow.

Moreover, like other embodiments, the kinetic heat sink may have an intake port that spans up to 360 degrees of the kinetic heat sink. The method may include separating the airflow at the exhaust port from air-flow at the intake port. The method may further hot swap the rack server with swappable hard disks.

In accordance with another embodiment, a rack server has a server housing forming an interior chamber (having a front and a rear), and a base supporting a plurality of circuit elements. The circuit elements include at least one processor and at least one memory module. The rack server also has a kinetic heat sink in direct contact with the at least one processor. This direct contact is configured to produce a heat-conduction relationship between the at least one processor and the kinetic heat sink. The kinetic heat sink has a radial side spanning 360 degrees. The rack server also has an exhaust port for radially directing air from the kinetic heat sink. The exhaust port spans no more than about 180 degrees of the radial side. Moreover, the kinetic heat sink is configured to exhaust air from no more than about 180 degrees of the radial side. The at least one memory module is positioned between the kinetic heat sink and the rear of the chamber. Moreover, the kinetic heat sink is positioned between the front of the chamber and the at least one memory module. The exhaust port faces the rear of the chamber and is configured to direct air toward the rear of the chamber to cool the at least one memory module.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows a kinetic-heat-sink-cooled server according to an illustrative embodiment.

FIG. 2 schematically shows the server of FIG. 1.

FIGS. 3A and 3B schematically illustrate a kinetic heat sink assembly according to an alternative embodiment.

FIG. 4 schematically shows the kinetic heat sink assembly of FIG. 1.

FIG. 5 schematically shows a cut-away view of a disassembled kinetic heat sink according to an illustrative embodiment.

FIG. 6A schematically shows a cross-sectional view of the assembled kinetic heat sink of FIG. 5.

FIG. 6B schematically shows the kinetic heat sink of FIG. 5 according to an alternative embodiment.

FIG. 7 schematically shows a cross-sectional view of a kinetic heat sink assembly for cooling multiple processors according to an alternative embodiment.

FIGS. 8A and 8D schematically show cross-sectional views of kinetic heat sink assemblies for cooling multiple processors according to another alternative embodiment.

FIGS. 9A-9C schematically show the rotating member of a kinetic heat sink according to the various embodiments.

FIGS. 10 and 11 schematically show examples of inlet and outlet airflow from the various kinetic heat sink assemblies.

FIGS. 12-15 schematically show various topologies for kinetic heat sink assemblies having multiple rotating members.

FIG. 16 illustrate exemplary power consumption performance of a kinetic heat sink.

FIG. 17 illustrates an exemplary flow and pressure performance of a kinetic-heat-sink configured in accordance with illustrative embodiments.

FIGS. 18-21 schematically show various views of an embodiment of a kinetic-heat-sink-cooled server according to an illustrative embodiment.

FIGS. 22-23 schematically show various views of an embodiment of another kinetic-heat-sink-cooled server according to an illustrative embodiment.

### DESCRIPTION OF ILLUSTRATIVE EMBODIMENTS

In illustrative embodiments, a high-density computing system, such as a small form-factor rack mount server, is equipped with a kinetic heat sink to produce an internal air-flow for concurrently cooling the main and peripheral components therein—thereby reducing the need for case fans as conventionally used. Kinetic heat sinks of various embodiments both directly extract heat of a heated source and generate airflow. As such, an underlying computing system is capable of consuming less energy than it typically would consume if it used many known types of conventional cooling systems. In certain instances, the inventors find that the power consumption of illustrative embodiments may be less than half that of conventional systems. Details of illustrative embodiments are discussed below.

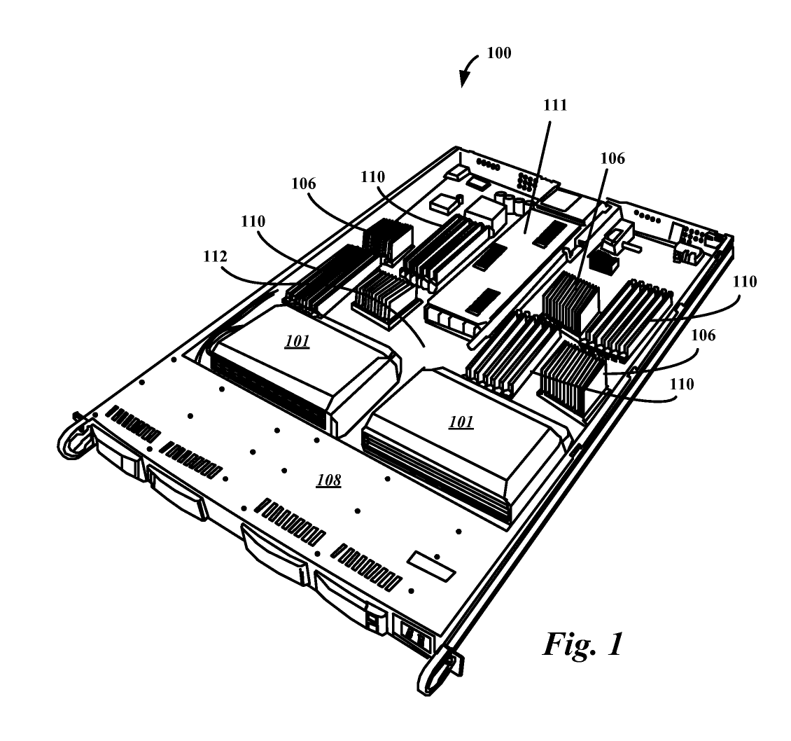

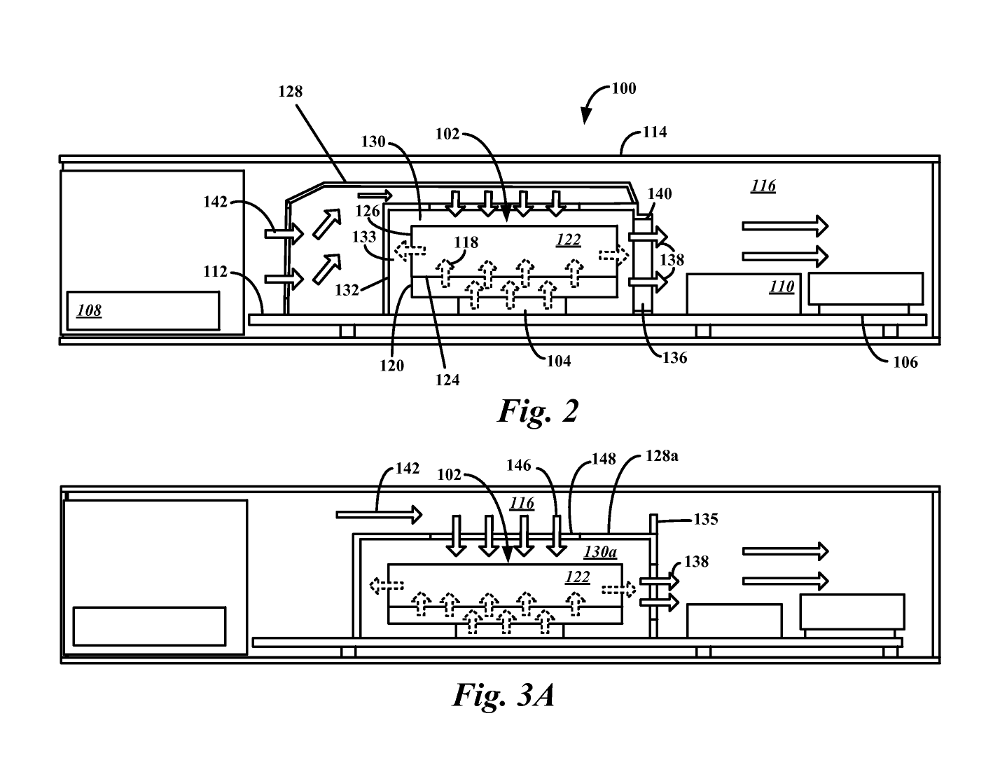

FIG. 1 schematically shows a kinetic-heat-sink-cooled server 100 (e.g., a rack server or non-rack server) configured according to an illustrative embodiment of the invention. The server 100 includes a kinetic-heat-sink apparatus 102 (see FIG. 2) for cooling both the main- and peripheral-circuit elements of the server 100. The server 100, thus, may operate advantageously without case-fans or other cooling topologies. It should be noted that although case fans and other cooling topologies may not be necessary, they may be employed to augment the cooling performance of such computing systems. Accordingly, discussion of servers without cooling fans is not intended to limit all embodiments of this invention.

To concurrently cool the main- and peripheral-circuit elements, at least one kinetic-heat-sink apparatus 102 is preferably in direct contact with each of the main-circuit elements. In illustrative embodiments, this produces a conductive heat transfer relationship from the circuit element to the kinetic-heat-sink apparatus 102. Specifically, as known by those in the art, the server 100 expends energy to perform computation tasks, which are carried out primarily by the main-circuit elements, including a processing component 104 (see FIG. 2), such as a central processing unit (CPU), a graphic processing units (GPU), a digital signal processing (DSP) unit, a field-programmable gate array (FPGA), a system-on-a-chip (SoC), a microprocessor, or an ASIC with a processor core, in a single-chip package. A typical 1U server may have between one and four main-circuit elements, which may each have multiple cores. Each of the main-circuit elements may mount to the base 112 through a socket assembly.

The kinetic-heat-sink apparatus 102 generates air-flow both 1) to expel heat drawn from the main-circuit elements to the kinetic-heat-sink apparatus 102 and 2) to direct the expelled air over the peripheral-circuit elements, such as chipsets 106 (see FIG. 2), hard disks 108 (see FIG. 2), and memory modules 110. The processing component 104, the chipsets 106, and the memory modules 110 are typically supported on a base 112, which may include a main printed-circuit board, often referred to as a motherboard, or another interconnect apparatus. In this figure, the chipsets 106 directly contact a passively cooled finned heat sink and are disposed between the base 112 and the heat sink. The chipsets 106 may include various integrated circuits (IC), such as the Southbridge IC, which can be sufficiently cooled by passive thermal leakage mechanisms. Of course, the base 112 may be a secondary printed-circuit board that is coupled to the main printed-circuit board. Other components in the server 100 may include the power supply 111. The hard disks 108 (see FIG. 2) may be part of a drive assembly, and may be positioned at the front of the server 100, configured for hot-swappable operations.

It is noted that the term “chipsets 106” refers to a single thermal element comprising a chip as well as its heat sink. Similarly, the terms “memory modules 110” and “hard disks 108” refer to a plurality of independent thermal elements in which each may comprise, respectively, a circuit board with memory chips as well as any attached fin- or heat-sink-components or a drive assembly in thermal contact with a hard disk. The hard disks 108 may be of various types, such as 2.5″ drive, a 3.5″ drive, and a 5.25″ drive. The memory modules 110 may be of various types, such as 184-pin DDR SDRAM, a 200-pin DDR2 SO-DIMM, a 204-pin DDR3 SO-DIMM, a 240-pin DDR2 FB-DIMM, a 240-pin DDR2 SDRAM, and a 240-pin DDR3 SDRAM.

FIG. 2 schematically shows a cross-sectional view of the server 100 of FIG. 1, viewed from the side. The server 100 includes a server housing 114 having an interior that forms a chamber 116. In the chamber 116, the kinetic-heat-sink apparatus 102 directly contacts the processing component 104 such that a heat-conduction relationship 118 exists between them, including through a thermal interface layer. For example, a thermal film, such as thermal paste or thermal grease, may be applied between the processing component 104 and the kinetic-heat-sink apparatus 102 to mitigate any potential air pockets between the two elements 102 and 104.

In various embodiments, the kinetic-heat-sink apparatus 102 comprises a thermal base structure 120 and a rotating structure 122, in which the thermal base structure 120 directly contacts the processing component 104 (e.g., via the thermal film or an adhesive). The rotating structure 122 is spaced from the base structure 120 by a small spatial gap 124 measuring preferably less than 100 micrometers. When rotating, heat more readily transfers (as compared to when the rotating structure 122 is stationary) from the thermal base structure 120 to the rotating structure 122. In some implementations, a reasonable magnitude of the thermal resistance for the gap 124 is less than about 0.11° Celsius/Watt. In other implementations, the thermal resistance is preferably less than 0.05° Celsius/Watt or 10° Celsius·cm²/Watt.

The rotating structure 122 (and thus, the kinetic-heat-sink apparatus 102) has a radial side 126 spanning 360 degrees—the region around the rotating structure 122. As shown by the arrows in FIG. 2, the rotating structure 122 forces air to flow, radially outwardly, generally by centrifugal mechanisms.

A wall member 132 radially directs the air expelled from the rotating structure 122 to circulate in a space 133 between the wall member 132 and the rotating structure 122 toward an exhaust port 136. The space 133 has a minimum distance between two opposing surfaces measuring preferably at least about 3 millimeter (mm) in length, more preferably between about 5 and 10 mm. The distance may increase angularly to at least 20 mm in some embodiments, even more preferably between 20 and 50 mm, and even more preferably at about 45 mm.

The kinetic-heat-sink apparatus 102 also may include a kinetic-heat-sink housing 128, which forms a chamber 130 to contain some or each of the thermal base structure 120 and the rotating structure 122. The chamber 130 may be formed from the wall member 132 and the exhaust port 136, and incorporate the space 133.

The exhaust port 136 guides/directs the output flow of the kinetic-heat-sink-apparatus 102 and spans preferably no more than about 180 degrees of the radial side 126 (e.g., 90 degrees or less). In other words, the exhaust port 136 does not cover/span/extend more than 180 degrees of the overall kinetic-heat-sink apparatus 102. To that end, the port 136 directs what may be considered to be a “vector” of exhaust air 138 toward no more than about 180 degrees of the radial side 126 of the rotating structure 122. More specifically, those skilled in the art recognize that the exhaust air 138 initially is directed from the exhaust port 138 in a substantially linear direction. Of course, that air stream will begin to expand outwardly in a diverging pattern after a certain distance. The small distances within the server apparatus 100, however, do not give the air stream enough distance to expand a substantial amount, thus causing the vector of air to flow in the desired direction—toward other circuit elements. Accordingly, a majority of the exhaust air 138 directed from the exhaust port 138 preferably is directed toward pre-specified circuit elements.

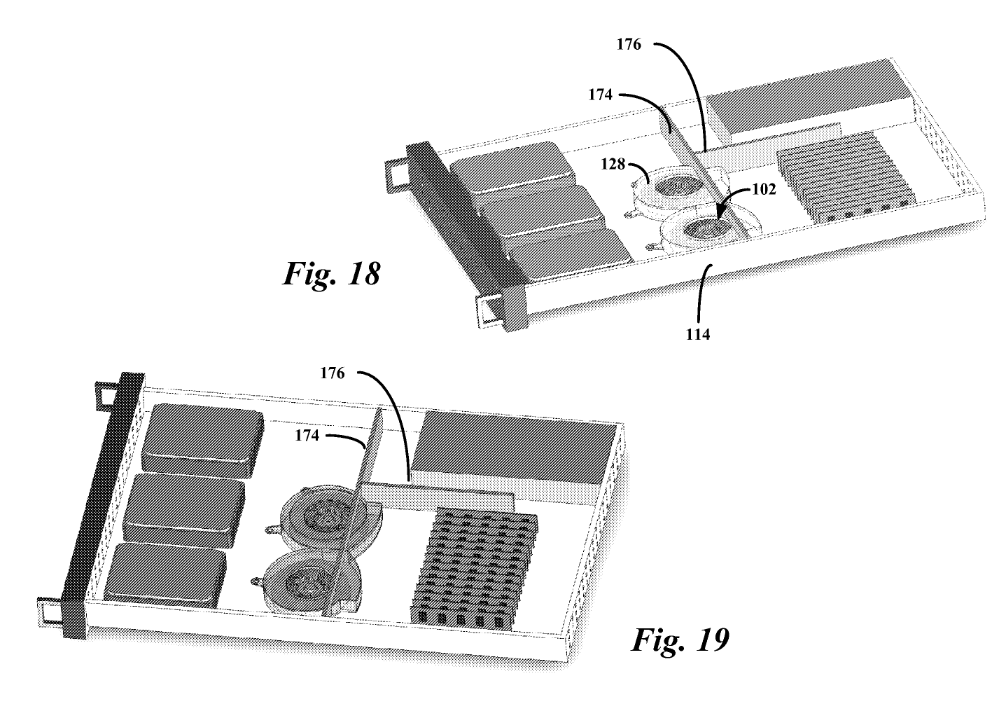

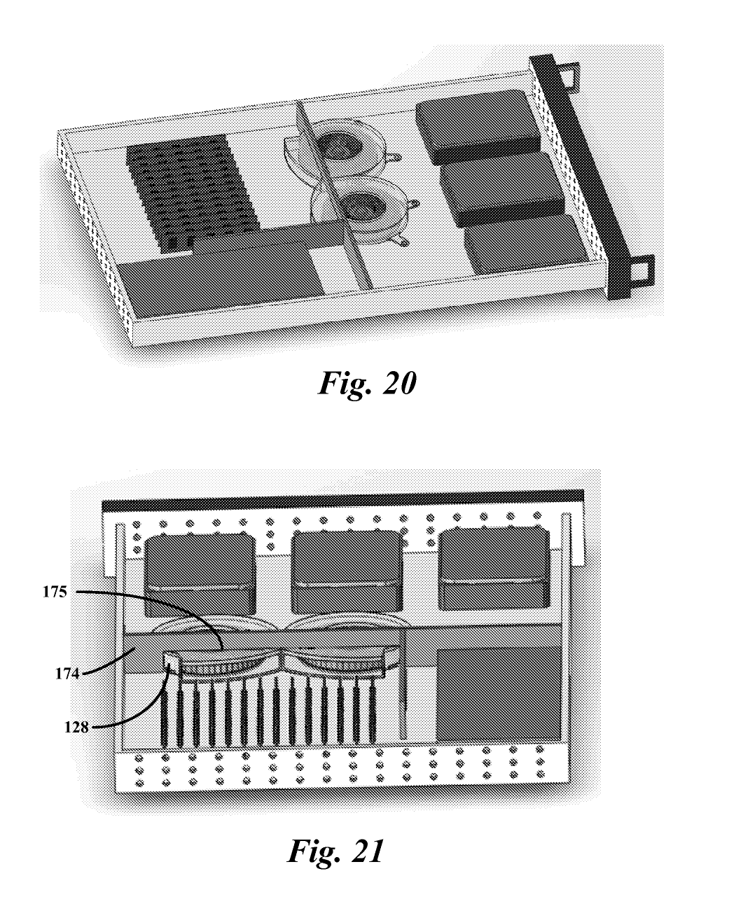

The exhaust port 136 thus preferably faces/is oriented and is configured to direct the air 138 toward at least one peripheral-circuit elements located between the kinetic-heat-sink apparatus 102 and the rear of the server housing 114. For example, as shown in FIG. 1, the exhaust port 136 may direct air-flow toward the chipsets 106 and the memory modules 110. The exhaust port 136 may be formed from a surface 140 that separates the exhaust air-flow 138 of the kinetic-heat-sink apparatus 102 from the intake air-flow 142. In this figure, the surface 140 is a part of a stand-alone kinetic-heat-sink housing 128. In other embodiments, the surface 140 may be a part of the server housing 114 (see, for example, FIGS. 18-23), which also serves as the kinetic-heat-sink housing 128.

Other embodiments may have multiple exhaust ports 136 that direct air in different directions. For example, one exhaust port 136 may direct air rearwardly, while another may direct exhaust air toward the rear and side of the rack server, or even toward the front. Some embodiments limit total extent of all these exhaust ports 136 to cover no more than about 180 degrees of the kinetic-heat-sink apparatus 102. Others permit a greater extent for the total extent of these exhaust ports 136.

FIG. 4 schematically shows the kinetic heat sink assembly of FIG. 2, which has the housing 128 and kinetic-heat-sink apparatus 102. In this embodiment, the chamber 130 of the housing 128 is partitioned into at least two sub-chambers, including a heat-rejection chamber 130a and a nozzle chamber 130b. The heat-rejection chamber 130a contains the kinetic-heat-sink apparatus 102, which rotates to draws air 146 from the nozzle chamber 130b. The nozzle chamber 130b, in turn, guides the air from the server chamber 116 to the heat-rejection chamber 130a and also partitions the exhaust air 138 from being drawn back into the kinetic-heat-sink apparatus 102. The wall member 132 may separate the chambers 130a, 130b. The housing 128 may be made of conventional materials, including metals, such as aluminum, nickel, brass, copper, etc., or thermoplastics, such as polyurethane and polypropylene.

As the rotating structure 122 rotates, air (shown as arrow 144) flows radially outwardly, generally due to centrifugal mechanisms. The wall member 132 directs the air (shown as arrow 144) toward the exhaust port 136. As the rotating structure 122 forces air (shown as arrow 144) to move, it draws the air 146 through an intake port 148 located between the heat-rejection chamber 130a and the nozzle chamber 130b. The air movement rejects heat 144 into the heat-rejection chamber 130a, forming a temperature gradient (i.e., ΔT) between the processing component 104 and the solid structure of the kinetic-heat-sink apparatus 102. This thermal gradient draws heat 150 from the processing component 104 and spreads the heat across the thermal base structure 120. A portion 153 of this heat 150 then transfers to the rotating structure 122 across the spatial gap 124 and is rejected into the heat-rejection chamber 130a through the rotating structure 122.

The heat-rejection chamber 130a preferably comprises a rounded chamber, though other shapes, such as ovals, may be employed. In the heat-rejection chamber 130a, as indicated above, the space 133 between the wall member 132 of the heat-rejection chamber 130a has a minimum distance between two opposing surfaces measuring preferably at least about 3 millimeter (mm) in length, preferably between about 5 and 10 mm, even more preferably at about 6 mm. In certain implementations, the space 133 may increase angularly to at least 20 mm, even more preferably between 20 and 50 mm, even more preferably at about 45 mm. Of course, other dimensions may be employed for different sizes of rotating structure 122.

The nozzle chamber 130b comprises a shell that extends forwardly toward a nozzle inlet port 152, which preferably is located and facing toward the front of the server 100. The shell is shaped so as to funnel air toward the back region 153 of the nozzle chamber 130b, located above the rotating structure 122, to which the intake port 148 is located. The back region 153 has a clearance height that measures preferably at least about 2 mm, even more preferably between about 2 and 15 mm, and even more preferably between about 3 and 12 mm. The nozzle chamber 130b may include a wall member between the nozzle inlet port 152 and intake port 148 to minimize flow resistance therebetween. This wall member may be angled, sloped, or curved.

The intake port 148 is preferably located both above the rotating structure 122 and between the nozzle chamber 130b and the heat-rejection chamber 130a. The space, between the intake port 148 and the rotating structure 122, measures preferably greater than about 0.5 mm, more preferably between about 1 and 5 mm, and even more preferably between about 1 and 2 mm. The intake port 148 may be shaped as a circle, an oval, or a slot.

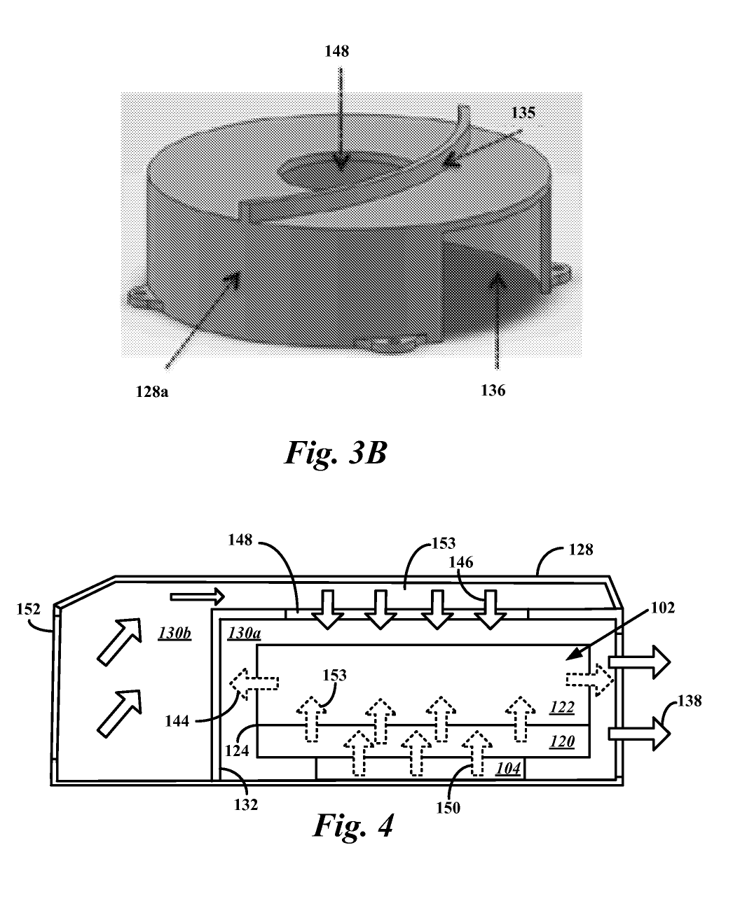

FIGS. 3A and 3B schematically illustrate a kinetic heat sink assembly comprising an alternate embodiment of the kinetic-heat-sink housing 128 (referred to as “housing 128a”). As shown in FIGS. 3A and 3B, the housing 128a forms a single chamber, namely the heat-rejection chamber 130a. Air 146 is directly fed from the server chamber 116 to the rotating structure 122 through the intake port 148. The housing 128a includes a bevel member 135 to partition the exhaust air-flow 138 of the kinetic-heat-sink apparatus 102 from the intake air-flow 142. The housing 128a may be molded or cast as a unitary structure. The housing 128a may also be made of materials, including metals (such as aluminum, nickel, brass, copper, etc.) or thermoplastics (such as polyurethane, polypropylene, polyethylene, acrylic, nylon, polystyrene, polyvinyl chloride, etc.).

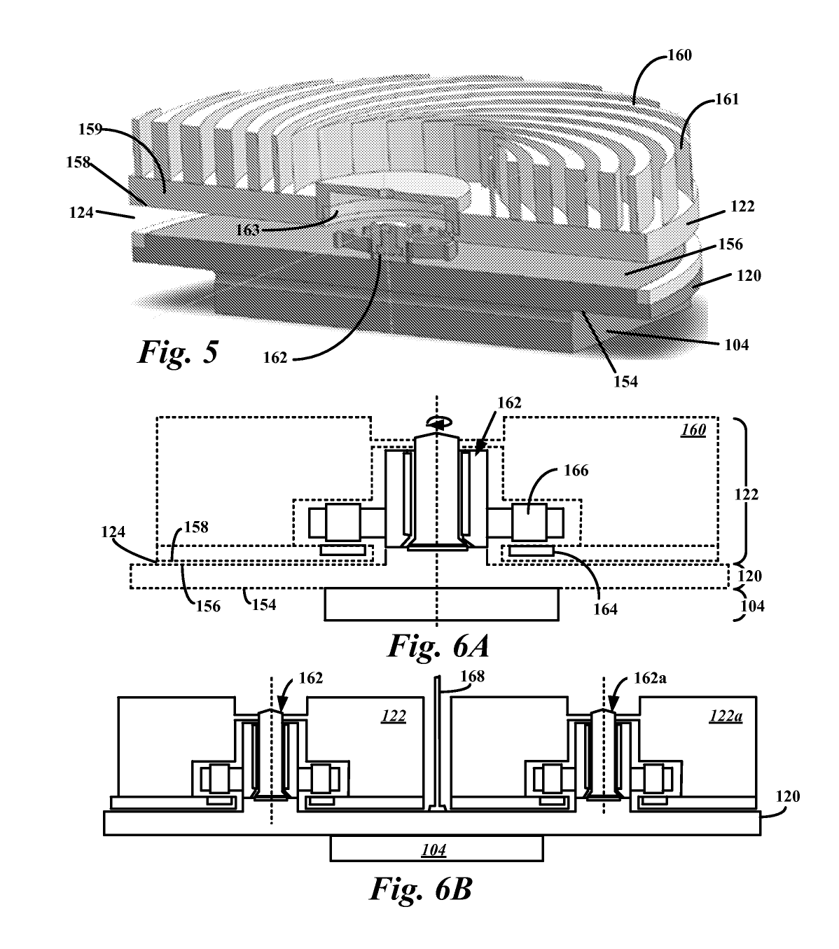

Details of the kinetic-heat-sink apparatus 102 are now discussed with reference to FIGS. 5 and 6. FIG. 5 shows a cross-sectional, partially exploded view of a disassembled kinetic-heat-sink apparatus 102. FIG. 6A schematically shows details the assembled kinetic-heat-sink apparatus 102 of FIG. 5.

The thermal base structure 120 includes a stationary component that directly contacts the processing component 104, and/or other circuit elements. As noted above, various mounting mechanisms may be employed, such as screws, bolts, rivets, solder, and adhesives. The thermal base structure 120 includes a first heat-conducting surface 154 and a second heat-conducting surface 156 to conduct heat therebetween and has a thickness measuring preferably between about 2 mm and 10 mm, even more preferably between about 4 and 6 mm. These heat-conducting surfaces 154, 156 may form the footprint of the kinetic-heat-sink apparatus 102. In certain embodiments, the second heat-conducting surface 156 is generally parallel to the first heat-conducting surface 154 (i.e., having less than 5 degree variation). In other embodiments, these surfaces 154, 156 may be generally perpendicular to one other—for example, where the second heat-conducting surface 156 forms concentric rings (not shown) that interdigitate with structures of the rotating structure 122.

The rotating structure 122, which is rotatably coupled to the thermal base structure 120, may comprise a platen region 159, fluid-directing structures 160, and a motor component region 163. The platen region 159, on one of its sides, includes a heat-extraction surface 158, which faces the second heat-conducting surface 156 across the fluid gap 124. The platen region 159 may have a foot print measuring preferably between about 10 and 100 squared inches (in²), more preferably between about 10 and 20 in². Of course, smaller and larger dimensions may be employed in other computing system depending on the size of the application.

The fluid-directing structures 160 (such as fins or blades) preferably extend from the other side of the platen region 159 and form channels 161 within the rotating structure 122. These channels 161 may have a width (constant or varying) measuring preferably at least about 0.1 mm, more preferably at least about 1 mm, even more preferably between about 1 and 5 mm. The fluid-directing structures 160 may have a radial length measuring preferably between about 1 and 3 inches, even more preferably between 1 and 2.5 inches.

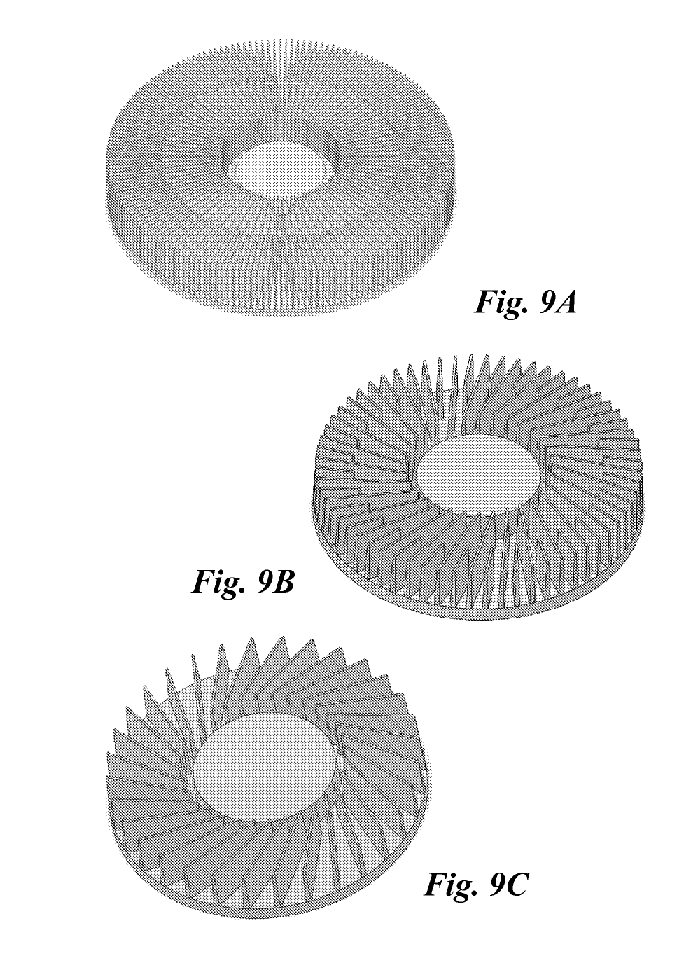

Various topologies of the fluid-directing structures 160 may be employed. FIGS. 9A-9C schematically show the rotating structure 122 of a kinetic-heat-sink apparatus 102 according to the various embodiments. In certain embodiments, the fluid-directing structures 160 may be configured as two sets of interleaving short and long straight fins (see, for example, FIG. 9A). In some embodiments, each of the fins may be oriented along a radial axis of the rotating structure 122 (see, for example, FIGS. 9B and 9C). The set of interleaved straight fins may be angled with respect to the radial axis, for example, between about 20 and 50 degrees. Of course, other embodiments may be employed. For example, the fluid-directing structures 160 may be configured as forwardly or backwardly oriented fins.

During operation, the rotating structure 122 rotates and receives heat 153 (see FIG. 4) from the second heat-conducting surface 156 through the gap 124. The rotating structure 122 expels the received heat to the thermal reservoir (e.g., heat-rejection chamber 130a) in communication with the rotating structure 122. In certain embodiments, the thermal resistance of the kinetic-heat-sink apparatus 102 may be modeled as having an exponential relationship, for example, as provided in Equation 1. It should be apparent to one skilled in the art that though a portion of the heat at the second heat-conducting surface 156 may dissipate directly to the thermal reservoir (e.g., chamber 130b) by natural convection and radiation mechanisms (also referred to as thermal leakage), a substantial portion of the heat transfers across the gap 124 by a non-negligible amount beyond such thermal leakage mechanisms.

R=0.15+2.0e^{(-0.8*CFM)} (Equation 1)

During rotation, the spatial gap 124 has a distance that measures preferably less than about 100 um, more preferably between 5 and 50 um, and even more preferably between about 10 and 25 um. In certain embodiments, such as where the gap 124 is between two vertical fins (formed in the thermal base structure 120 and the rotating structure 122 that are concentric and interdigitated), the gap 124 may be larger by a factor of two to three.

A motor assembly 162 is preferably located between the thermal base structure 120 and the rotating structure 122 to rotate the rotating structure 122. In an embodiment, the motor assembly 162 comprises a stator portion 164 fixably attached to the thermal base structure 120 and a rotor portion 166 attached to the rotating structure 122 (at the motor component region 163). Various motor configurations may be used, including, for example, a direct-current-based motors (such as brushed DC motors, permanent-magnet electric motors, brushless DC motors, switched reluctance motors, coreless DC motors, universal motors) or an alternating-current-based motors (such as single-phase synchronous motors, poly-phase synchronous motors, AC induction motors, and stepper motors). The motor may employ various types of bearings to maintain centricity of the rotation, including hydrodynamic bearings, mechanical bearings, air bearings, and magnetic bearings.

Various other details and examples of the kinetic-heat-sink apparatus 102 are described in U.S. patent application Ser. No. 13/911,677, filed Jun. 6, 2013, titled “Kinetic heat sink having controllable thermal gap” and U.S. provisional application, Ser. No. 61/868,362, filed Aug. 21, 2013, titled “Kinetic heat-sink with concentric interdigitated heat-transfer fins.” These applications are incorporated by reference herein in their entireties.

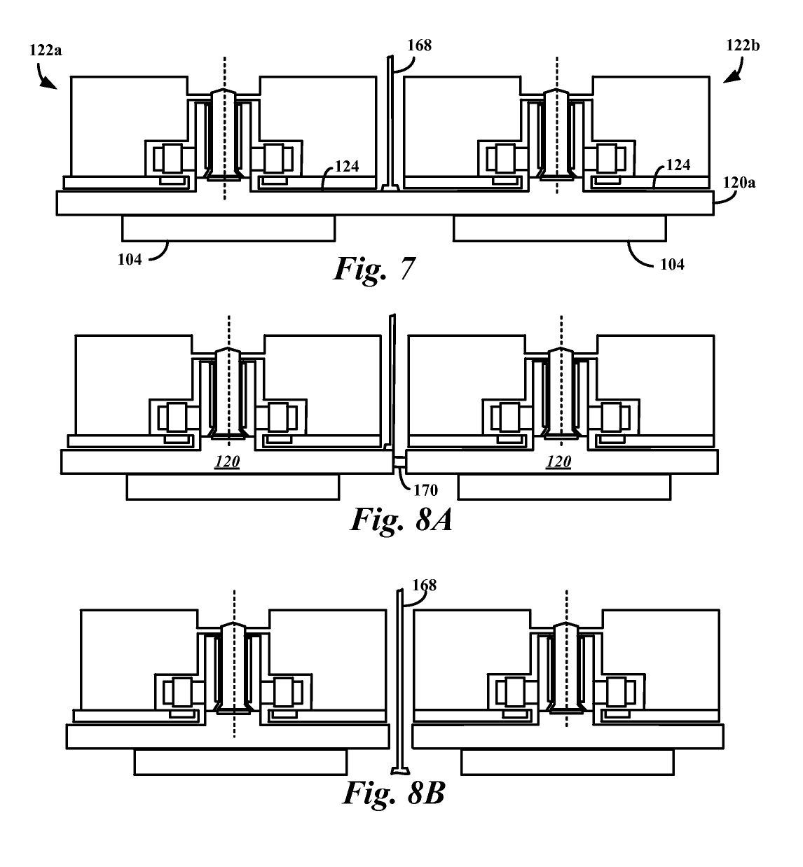

Other topologies may be employed. FIG. 6B, for example, schematically shows the kinetic heat sink of FIG. 5 according to an alternative embodiment. A second rotating structure 122a is coupled to the thermal base structure 120 by a second motor assembly 162a. A partitioning wall 168 may be disposed between the rotating structures 122 and 122a. In another embodiment of the invention, a single kinetic-heat-sink apparatus 102 may be employed to directly/conductively cool multiple processing-components 104. To that end, FIG. 7 schematically shows a kinetic-heat-sink assembly coupled to multiple processing-components 104 according to another illustrative embodiment. By positioning at least two processing components 104 adjacent to each other, a common thermal base structure 120a may be employed between at least two processing components 104.

The thermal base structure 120a may directly contact such components 104 in a manner described above. The thermal base structure 120a in this example couples to at least two rotating structures 122a, 122b across the fluid gap 124. A partitioning wall 168 may be disposed between the rotating structures 122a, 122b to partition the air expelled from the structures 122a, 122b. The structures 122a, 122b may be contained in the housing 128 in which the partitioning wall 168 forms a part thereof. Each of the rotating structures 122a, 122b preferably includes the exhaust port 138.

In such configuration, the rotating structures 122a, 122b may have a diameter measuring preferably between about 60 and 100 mm, more preferably between about 80 and 90 mm, and even more preferably at about 89 mm.

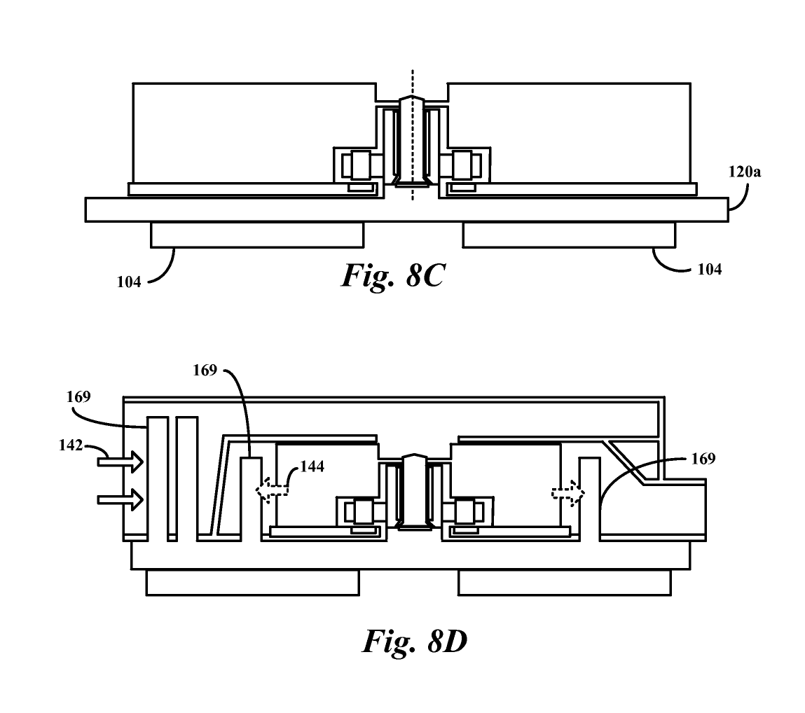

FIGS. 8A and 8D schematically show kinetic-heat-sink assemblies for cooling multiple processors according to another alternative embodiment. In FIG. 8A, at least two thermal base structures 120 may exchange heat through an embedded heat pipes 170 located between them. In FIG. 8B, two kinetic-heat-sink apparatuses (102) separated by a partitioning wall 168 disposed therebetween. In FIG. 8C, at least two processing components 104 share a common thermal base structure 120a coupled to a single rotating structure 120.

In FIG. 8D, the common thermal base structure 120a may include stationary fins 169, which may extend from the second heat-conducting surface 156 into the heat-rejection chamber 130a and/or the nozzle chamber 130b. The surface area of stationary fins 169 adds a secondary heat-transfer component for the kinetic-heat-sink apparatus 102 in additional to the rotating structure 122. The intake air-flow 142 and radial flow (shown as arrow 144) may assist the stationary fins 169 in rejecting heat in to the surrounding air by convective mechanisms. Various other details and examples of stationary fins 169 are described in U.S. provisional application, Ser. No. 61/816,450, filed Apr. 26, 2013, titled “Kinetic heat-sink with stationary fins.” This application is incorporated by reference herein in its entirety.

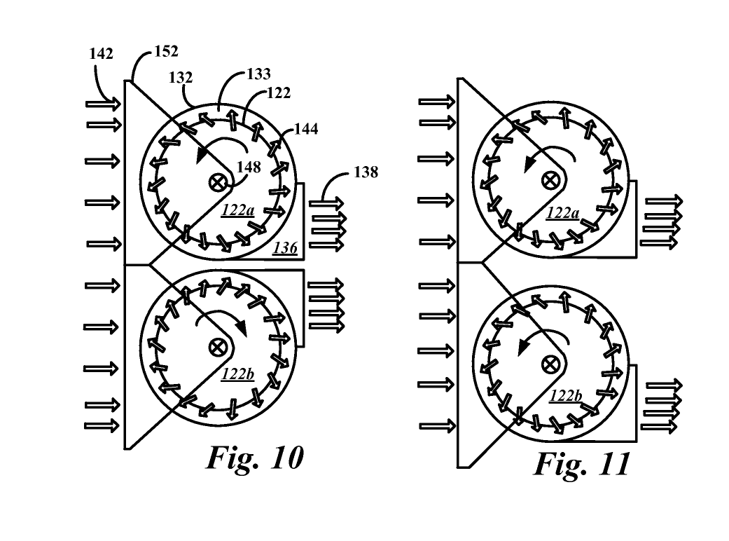

FIGS. 10 and 11 schematically show top view examples of inlet and outlet air-flow of the kinetic-heat-sink assemblies of FIG. 7. Air 142 enters through the nozzle inlet port 152 and is directed to the intake port 148. As the air flows through the port 148 to the rotating structure 122, it is radially forced (see arrow 144) from the rotating structure 122 to the wall member 132. The wall member 132 radially directs the expelled air (shown as arrow 144) to circulate in the space 133 toward the exhaust port 136. The exhausted air 138 is thus preferably directed as a vector toward peripheral components located at the rear of the server 100. In FIG. 10, the rotating structures 122a, 122b rotate in opposite directions. In FIG. 11, the rotating structures 122a, 122b rotates in the same direction. The air (shown as arrow 144) flows in a given direction mainly due to centrifugal mechanisms from the rotational movements of the rotating structures 122a, 122b. The centrifugal force density that causes the outward flow direction of the impellers 1008, 1016 may be expressed as fᵣ=½ ρrω², where ρ is the fluid density, r is the radial location of the force, and ω is the angular velocity.

The kinetic-heat-sink apparatus 102 is configured to provide the same or similar cooling and airflow as presently generated by an array of case fans. Specifically, the kinetic-heat-sink apparatus 102 is configured to generate a pressure rise of 0.2 inch-water (in.-H₂O) in the chamber 116 in order to sufficiently generate an air-flow comparable to conventional cooling methods. To do so, the kinetic-heat-sink apparatus 102 is configured produces a local pressure rise at the apparatus of 0.2 in.-H₂O.

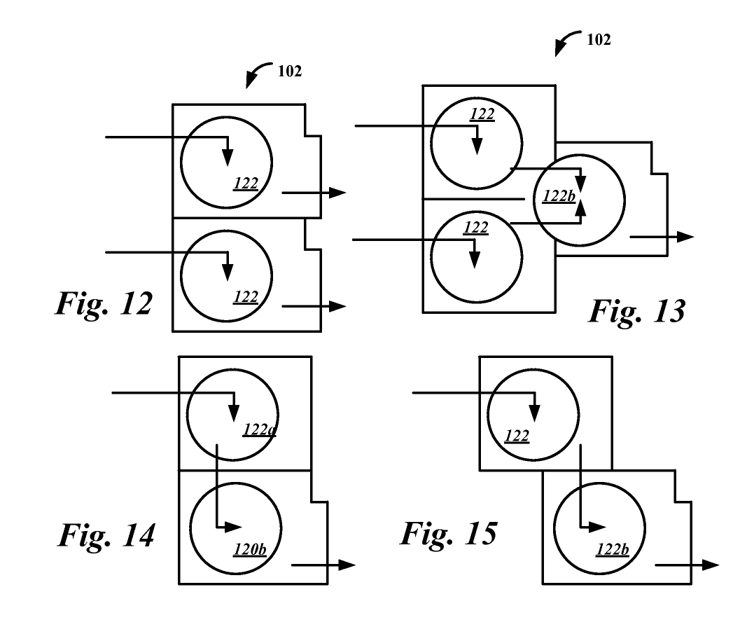

To produce such a pressure rise and airflow, multiple rotating structures 122 may be employed either in a serial or parallel configuration. See, for example, FIGS. 12-15. In FIG. 12, two rotating structures 122 operate in a parallel configuration. A second-stage rotating-structure 122b is employed in FIG. 13 to increase the pressure rise produced by the kinetic-heat-sink apparatus 102. The second stage rotating-structure 122b receives parallel-outputted flow from the two rotating structures 122. In FIGS. 14 and 15, the output of a single rotating structure 122 is fed to the second stage rotating structure 122b. Note that other embodiments may use a single base 120 and a single rotating portion 122 to cool multiple components.

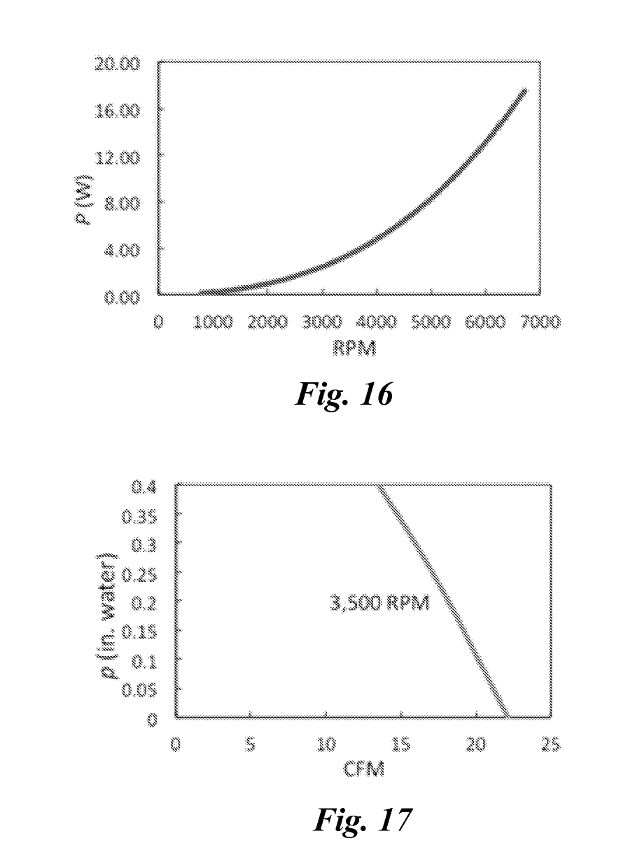

FIG. 16 graphically illustrate an exemplary power consumption profile of a kinetic-heat-sink-apparatus 102. FIG. 17 graphically illustrates an exemplary flow and pressure performance of the kinetic-heat-sink apparatus. As shown in the figures, for each kinetic-heat-sink apparatus 102 to generate approximately 20 CFM and 0.1 in. water pressure in the chamber 116 when operating at 3,500 RPM, the kinetic-heat-sink apparatus 102 may draw 3.45 Watt of power. This flow is comparable to performance of an array of conventional case fans and, thus, may be sufficient to cool all of the peripheral components. The details of the operation of an embodiment of the kinetic-heat-sink apparatus 102 at various power levels is provided in Table 1.

TABLE 1

| | @70% | @100% |
|---|---|---|
| | processing | processing |
| Parameter | power | power |
| Number of heat sinks | 2 | 2 |
| Number of case fans | 0 | 0 |
| Footprint (fans and | 26.0 in² | 26.0 in² |
| heat sinks) | | |
| Total airflow | 40 CFM | 65 CFM |
| Total pressure drop | 0.1 in. water | 0.5 in. water |
| Total fan power | 6.9 W | 37 W |
| consumption | | |
| Rotational speed | 3,500 | 6,800 |
| Server temperature | 18 C. | 13.5 C. |
| rise | | |
| Heat sink R_{c-a} | 0.33 C/W | 0.265 C/W |

FIGS. 18-21 schematically show various views of an embodiment of a kinetic-heat-sink-cooled server (rack or otherwise) according to another illustrative embodiment. The server 100 includes a server-wall member 174 to partition the exhaust flow 138 (see FIG. 4) from the inlet flow 146 (see FIG. 4). The server-wall member 174 may be a plate that is mounted to the interior of the server housing 114. The member 174 may include a slit 175 (see FIG. 21) and shaped such that the member 174 may be disposed around the housing 128 of the kinetic-heat-sink apparatus 102.

The server 100 may include second server-wall member 178 to direct the flow 138 toward the peripheral components (shown as the memory modules 110).

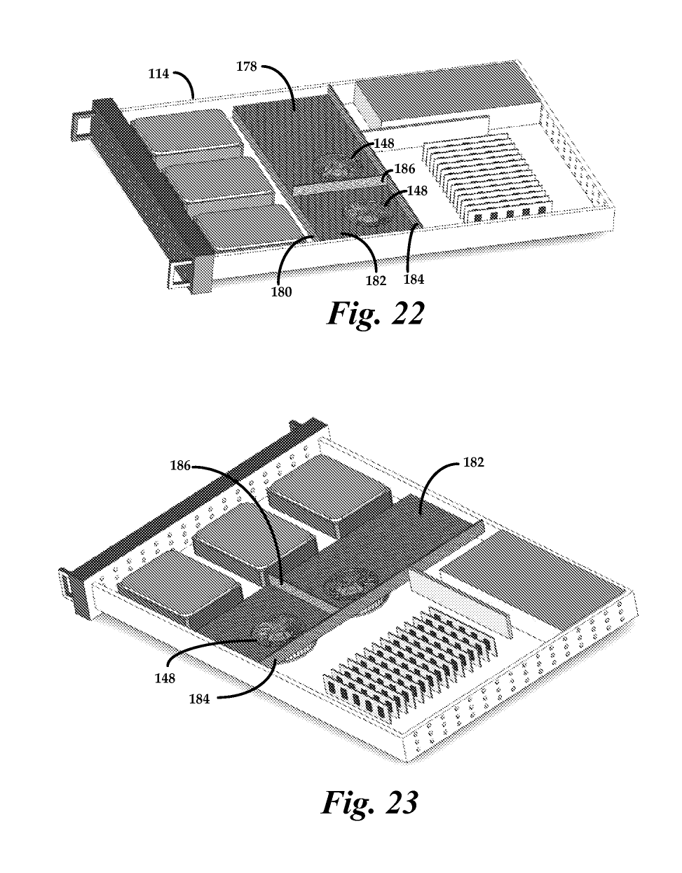

FIGS. 22-23 schematically show various views of an embodiment of another kinetic-heat-sink-cooled server according to an illustrative embodiment. The server 100 includes a server-wall member 178 disposed above the kinetic-heat-sink housing 128. The member 178 has a “straight-Z-shape” cross-sectional area to partition the exhaust flow 138 (see FIG. 4) from the inlet flow 146 (see FIG. 4). The member 178 comprises a front member 180, a middle member 182, and a back member 184, which all may span the width of the server housing 114. The member 178 may include an inlet wall 186 to partition the flow to the intake port 148 of each of the rotating structure 122.

During use, to begin cooling, a controller energizes the motor assembly 162 causing the rotating structure 122 to rotate. The power may be in VDC (e.g., 12V, 5V, etc.), VAC, or PWM. At a specified rotational speed, the rotating structure 122 allows heat to more readily transfer from the thermal base structure 120 to the rotating structure 122.

From the rotation, the fluid-directing structures 160 reject heat and direct it away to the thermal reservoir. A thermal-gradient results between the thermal base structure 120 and the rotating structure 122. Heat, thus, is drawn from the processing component 104, spread across the thermal base structure 120, transferred from the thermal base structure 120 to the rotating structure 122 across the spatial gap 124, and spread from the heat-extraction surface 158 to the fluid-directing structures 160.

As the fluid-directing structures 160 reject heat and direct it away to the thermal reservoir, they expel the fluid radially 360-degrees. The wall member 132 then directs the expelled air to circulate in the space between the wall member 132 and the rotating structure 122, and then to the exhaust port 136. The flow exits the kinetic-heat-sink apparatus 102, preferably as a vector of air-flow, toward the rear of the server 100. As the air flows over the peripheral components of the server, heat generated from such components also is rejected into the air, which then exits at the rear of the server 100. Accordingly, the exhaust air also serves to cool those additional peripheral components.

Also, as the fluid-directing structures 160 reject heat and direct it away to the thermal reservoir, they generate a vortex at about the center of the rotating structure 122. This vortex pulls intake air from the chamber 116 of the server housing 114. With the exhaust flow partitioned from the intake flow, the intake air is pulled from the front area of the server 100. This flow removes the heat rejected by peripheral components in the front of the server.

Although the above discussion discloses various exemplary embodiments of the invention, it should be apparent that those skilled in the art can make various modifications that will achieve some of the advantages of the invention without departing from the true scope of the invention.

What is claimed is:

1. A server comprising:
a base supporting a plurality of circuit elements;
a kinetic heat sink in direct contact with at least one first circuit element, the direct contact configured to produce a heat-conduction relationship between the at least one first circuit element and the kinetic heat sink, the kinetic heat sink having a radial side spanning 360 degrees; and
a member for radially directing air from the kinetic heat sink, the member having an exhaust port spanning no more than about 180 degrees of the radial side, the kinetic heat sink configured to exhaust air from no more than about 180 degrees of the radial side,
the exhaust port facing at least one second circuit element and configured to direct air toward the at least one second circuit element.

2. The server as defined by claim 1, wherein the exhaust port is configured to direct a vector of air toward the at least one second circuit element.

3. The server as defined by claim 1 further comprising:
a second kinetic heat sink in direct contact with at least one third circuit element, the direct contact configured to produce a heat-conduction relationship between the at least one third circuit element and the second kinetic heat sink, the second kinetic heat sink having a second radial side spanning 360 degrees; and
a second member for radially directing air from the second kinetic heat sink, the second member having a second exhaust port spanning no more than about 180 degrees of the second radial side, the second kinetic heat sink configured to exhaust air from no more than about 180 degrees of the second radial side, the second exhaust port facing the at least one third circuit element and configured to direct air toward the at least one third circuit element.

4. The server as defined by claim 1, wherein the kinetic heat sink comprises a thermal base structure in contact with the at least one first circuit element and a rotating structure spaced from the base structure by an air gap, the server further comprising a kinetic heat sink housing forming a chamber for containing the thermal base structure and rotating structure, the kinetic heat sink housing forming the exhaust port.

5. The server as defined by claim 4 further comprising a server housing containing the base, kinetic heat sink, and kinetic heat sink housing.

6. The server as defined by claim 4 further comprising a server housing containing the base and kinetic heat sink, the server housing comprising the kinetic heat sink housing.

7. The server as defined by claim 4, wherein the rotating structure has a footprint measuring between 10 and 20 squared inches (in²).

8. The server as defined by claim 1 further comprising duct structures configured to focus exhaust air from the exhaust port toward the at least one second circuit element.

9. The server as defined by claim 1 further comprising a wall structure configured to separate the exhaust air of the exhaust port toward the at least one second circuit element.

10. The server as defined by claim 1, wherein kinetic heat sink has an intake port spanning up to 360 degrees of the kinetic heat sink, the server further comprising a wall structure to separate the air-flow at the exhaust port from air-flow at the intake port,

11. The server as defined by claim 1, wherein the kinetic heat sink comprises a thermal base structure in contact with the at least one first circuit element and a rotating structure spaced from the base structure by an air gap, the air gap being less than about 100 microns.

12. The server as defined by claim 11, wherein the thermal base structure directly contacts at least two first circuit elements.

13. The server as defined by claim 11, wherein the kinetic heat sink includes at least two rotating structures spaced less than about 100 microns from a single thermal base structure.

14. The server as defined by claim 1 further comprising a server housing containing the base and kinetic heat sink, the server housing being configured to be mounted to a server rack in a prescribed manner, the server housing having a front portion to face the front of the server rack when mounted in the server rack, the server having an oppositely positioned rear portion, the majority of the exhaust port facing the rear portion for directing most of its air flow toward the rear portion of the server housing.

15. The server as defined by claim 1, wherein the exhaust port spans no more than about 90 degrees of the radial side.

16. The server as defined by claim 1 further comprising a plurality of kinetic heat sinks, each of the kinetic heat sinks being in direct contact with at least one circuit element.

17. The server as defined by claim 16, wherein the plurality of kinetic heat sinks has a common thermal base structure in contact with the at least two circuit elements.

18. The server as defined by claim 1 further comprising a thermal film between the kinetic heat sink and the at least one first circuit element.

19. The server as defined by claim 1, wherein the kinetic heat sink exhausts air at a flow rate measuring between 15 and 45 cubic feet per minute (CFM).

20. The server as defined by claim 1, wherein the kinetic heat sink draws air at a flow rate measuring between 15 and 45 cubic feet per minute (CFM).

21. The server as defined by claim 1, wherein server is a rack server.

22. The server as defined by claim 21, wherein the second kinetic heat sink comprises the thermal base structure in contact with the at least one first circuit element and the at least one third circuit element.

23. The server as defined by claim 22, wherein the second kinetic heat sink further comprises a second rotating structure spaced from the base structure by a second air gap, the second air gap being less than about 100 microns.

24. The server as defined by claim 21, wherein the server has a 1U form factor.

25. A method of thermally controlling the interior of a server, the method comprising:
mounting at least one kinetic heat sink to an integrated circuit within a server having a base supporting the integrated circuit and a plurality of other circuit elements, mounting producing a direct heat-conduction relationship between the kinetic heat sink and the integrated circuit, the server having a front and a rear, the kinetic heat sink having an exhaust port spanning no more than about 180 degrees of the kinetic heat sink;
orienting the exhaust port of the kinetic heat sink to direct the majority of its air flow toward the rear of the server, at least one other circuit element being between the kinetic heat sink and the rear to receive the air flow.

26. The method as defined by claim 25 further comprising energizing the kinetic heat sink to cool the integrated circuit and the at least one other circuit element.

27. The method as defined by claim 25 further comprising exhausting the airflow at a rate measuring between 15 and 45 cubic feet per minute (CFM).

28. The method as defined by claim 25, wherein the kinetic heat sink has an intake port spanning up to 360 degrees of the kinetic heat sink, the method further comprising separating the air-flow at the exhaust port from air-flow at the intake port.

29. A rack server comprising:
a server housing forming an interior chamber having a front and a rear;
a base supporting a plurality of circuit elements, the circuit elements including at least one processor and at least one memory module;
a kinetic heat sink in direct contact with the at least one processor, the direct contact configured to produce a heat-conduction relationship between the at least one processor and the kinetic heat sink, the kinetic heat sink having a radial side spanning 360 degrees; and
an exhaust port for radially directing air from the kinetic heat sink, the exhaust port spanning no more than about 180 degrees of the radial side, the kinetic heat sink configured to exhaust air from no more than about 180 degrees of the radial side,
the at least one memory module being between the kinetic heat sink and the rear of the chamber, the kinetic heat sink being between the front of the chamber and the at least one memory module,
the exhaust port facing the rear of the chamber and configured to direct air toward the rear of the chamber to cool the at least one memory module.

30. The rack server as defined by claim 29, wherein the exhaust port is configured to direct a vector of air toward the at least one memory module.

31. The rack server as defined by claim 29, wherein the kinetic heat sink comprises a thermal base structure in contact with the at least processor, and a rotating structure spaced from the base structure by an air gap, the air gap being less than about 100 microns.

32. The rack server as defined by claim 29, wherein the thermal base structure directly contacts at least two memory modules.
